(19) United States
(12) Patent Application Publication
(10) Pub. No.: US 2025/0105592 A1
(43) Pub. Date: Mar. 27, 2025

(54) LASER APPARATUS AND LASER PROCESSING MACHINE

(71) Applicant: Mitsubishi Electric Corporation, Tokyo (JP)

(72) Inventors: Masato KAWASAKI, Tokyo (JP); Hiroshi KIKUCHI, Tokyo (JP); Tomotaka KATSURA, Tokyo (JP)

(73) Assignee: Mitsubishi Electric Corporation, Tokyo (JP)

(21) Appl. No.: 18/729,943

(22) PCT Filed: Jan. 28, 2022
(86) PCT No.: PCT/JP2022/003301

§ 371 Date: Jul. 18, 2024

(51) Int. Cl. H01S 5/14; B23K 26/06; G02B 27/30; H01S 5/40

(52) U.S. Cl. CPC H01S 5/143; B23K 26/0608; B23K 26/0643; B23K 26/0648; G02B 27/30; H01S 5/4025

(57) ABSTRACT

A laser apparatus includes: a first laser device that forms a first beam group; a second laser device that forms a second beam group; an output mirror that constitutes an end of an external resonator; a converging optical system that allows non-parallel incidence of the first and second beam groups on the converging optical system; a diffraction grating disposed at an intersection at which at least a part of the first and second beam groups is superimposed, and having a diffraction effect in a plane perpendicular to a third direction that is a direction perpendicular to first and second directions; and a collimating optical system disposed between the diffraction grating and the output mirror, and collimating the first and second beam groups such that the first and second beam groups are incident perpendicularly on the output mirror while being spatially separated from each other.

### FIELD

The present disclosure relates to a laser apparatus and a laser processing machine, the laser apparatus amplifying a beam and outputting laser light.

### BACKGROUND

In a laser apparatus that amplifies a beam and outputs laser light, a laser device and an output mirror each constitute one end of a laser resonator. One of such laser apparatuses is a laser apparatus equipped with laser devices that emit beams from a plurality of light emitting points positioned in a horizontal direction in order to increase output of laser light. This laser apparatus increases the output of the laser light by superimposing the beams emitted from the plurality of light emitting points by a diffraction grating.

A laser apparatus described in Patent Literature 1 includes a plurality of laser devices stacked in a vertical direction and outputs beams of laser light equal in number to the number of the laser devices stacked, thereby outputting high-power laser light.

### CITATION LIST

### Patent Literature

Patent Literature 1: U.S. Pat. No. 8,488,245

### SUMMARY OF INVENTION

### Problem to be Solved by the Invention

However, in the technique of Patent Literature 1, the laser devices are stacked in the vertical direction so that a vertical dimension of a diffraction grating increases in proportion to the number of the laser devices stacked. For example, in a case where two layers of the laser devices are stacked in the vertical direction, the vertical dimension of the diffraction grating doubles. This leads to a problem that the diffraction grating becomes expensive.

The present disclosure has been made in view of the above, and an object thereof is to provide a laser apparatus capable of outputting high-power laser light using a diffraction grating that is small and inexpensive.

### Means to Solve the Problem

In order to solve the above problem and achieve the object, a laser apparatus of the present disclosure includes: a first laser device that emits a beam from each of a plurality of light emitting points, which is arranged in a first direction, in a first emission direction perpendicular to the first direction and forms a first beam group; and a second laser device that emits a beam from each of a plurality of light emitting points, which is arranged in a second direction, in a second emission direction perpendicular to the second direction and forms a second beam group. The laser apparatus of the present disclosure further includes: an output mirror constituting one end of a first external resonator, another end of which is constituted by the first laser device, constituting one end of a second external resonator, another end of which is constituted by the second laser device, and including a partial reflection surface that reflects a part of the first beam group and the second beam group and transmits the rest; and a converging optical system that allows non-parallel incidence of the first beam group and the second beam group on the converging optical system and, on a side of a subsequent stage, converges the first beam group such that the first beam group is superimposed and converges the second beam group such that the second beam group is superimposed. The laser apparatus of the present disclosure further includes: a diffraction grating disposed at an intersection at which at least a part of the first beam group and the second beam group is superimposed, and having a diffraction effect in a first plane perpendicular to a third direction that is a direction perpendicular to the first direction and the second direction; and a collimating optical system disposed between the diffraction grating and the output mirror, and collimating the first beam group and the second beam group such that the first beam group and the second beam group are incident perpendicularly on the partial reflection surface while being spatially separated from each other.

### Effects of the Invention

The laser apparatus according to the present disclosure has an effect of being able to output high-power laser light using the diffraction grating that is small and inexpensive.

### BRIEF DESCRIPTION OF DRAWINGS

FIG. 1 is a diagram illustrating a configuration of a laser processing machine including a laser apparatus according to a first embodiment.

FIG. 2 is a schematic diagram illustrating a schematic configuration of a laser apparatus according to the first embodiment.

FIG. 3 is a diagram illustrating a configuration of a laser apparatus according to the first embodiment in a case where a collimating optical system is two cylindrical lenses.

FIG. 4 is a diagram illustrating a configuration of a laser apparatus according to the first embodiment in a case where the collimating optical system is one cylindrical lens.

FIG. 5 is a schematic diagram illustrating a schematic configuration of a laser apparatus according to a second embodiment.

FIG. 6 is a diagram illustrating a configuration of a laser apparatus according to the second embodiment in a case where a superimposing optical system is two eccentric lenses.

FIG. 7 is a diagram illustrating a configuration of a laser apparatus according to the second embodiment in a case where the superimposing optical system is two deflection mirrors.

FIG. 8 is a schematic diagram illustrating a schematic configuration of a laser apparatus of a comparative example.

### DESCRIPTION OF EMBODIMENTS

Hereinafter, a laser apparatus and a laser processing machine according to embodiments of the present disclosure will be described in detail with reference to the drawings.

### First Embodiment

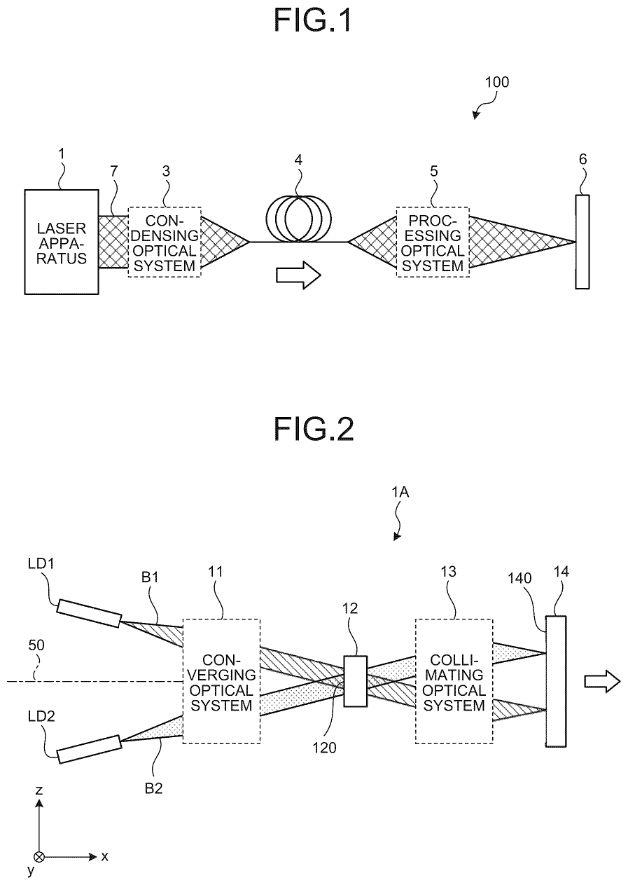

FIG. 1 is a diagram illustrating a configuration of a laser processing machine including a laser apparatus according to a first embodiment. A laser processing machine 100 is a machine that irradiates a workpiece 6, which is an object to be processed, with laser light 7 and processes the workpiece 6. The processing performed by the laser processing machine 100 is laser processing such as cutting or welding of the workpiece 6.

The laser processing machine 100 includes a laser apparatus 1 that emits the laser light 7, an optical fiber 4 through which the laser light 7 propagates, a condensing optical system 3, and a processing optical system 5. The condensing optical system 3 condenses the laser light 7 emitted from the laser apparatus 1 on an incident end surface of the optical fiber 4, The optical fiber 4 is an example of an optical transmission line that transmits the laser light 7. The optical fiber 4 transmits the laser light 7 to the processing optical system 5. The processing optical system 5 condenses the laser light 7 exiting the optical fiber 4 on the workpiece 6.

The workpiece 6 is, for example, a metal plate made of iron, stainless steel, or the like. The laser processing machine 100 can perform laser processing on the metal plate by including the laser apparatus 1 suitable for high-power applications. The configuration of the laser processing machine 100 described herein is an example, and may be modified as appropriate. The laser apparatus 1 can also be applied to a 3D printer or the like in combination with a configuration of a generally known laser processing machine. As with the laser apparatus 1, a laser apparatus to be described in second and subsequent embodiments can also be applied to the laser processing machine 100 that cuts or welds the workpiece 6 or to another laser processing system.

FIG. 2 is a schematic diagram illustrating a schematic configuration of a laser apparatus according to the first embodiment. FIG. 2 illustrates an x axis, a y axis, and a z axis of a three-axis orthogonal coordinate system. The y axis and the z axis are two axes that are orthogonal to each other and are in a plane parallel to a surface that is a flat surface being either a beam incident surface or a beam exit surface of a converging optical system 11. Moreover, an axis orthogonal to the y axis and the z axis is the x axis. An xy plane is, for example, a horizontal plane. In this case, a z-axis direction is a vertical direction. FIG. 2 illustrates a configuration of a laser apparatus 1A as an example of the laser apparatus 1 when the laser apparatus 1A is viewed from a y-axis direction.

The laser apparatus 1A includes a first laser device LD1 and a second laser device LD2 as laser devices. The laser apparatus 1A further includes the converging optical system 11, a diffraction grating 12, a collimating optical system 13, and an output mirror 14.

The converging optical system 11 is disposed in a stage subsequent to the first laser device LD1 and the second laser device LD2, and the diffraction grating 12 is disposed in a stage subsequent to the converging optical system 11. In addition, the collimating optical system 13 is disposed in a stage subsequent to the diffraction grating 12, and the output mirror 14 is disposed in a stage subsequent to the collimating optical system 13.

In the laser apparatus 1A, the first laser device LD1 and the second laser device LD2 are disposed apart from each other in the z-axis direction. The first laser device LD1 and the second laser device LD2 are disposed in a non-parallel manner, and a first beam group B1 emitted by the first laser device LD1 and a second beam group B2 emitted by the second laser device LD2 are not parallel. That is, the first laser device LD1 and the second laser device LD2 are each disposed at an angle such that the first beam group B1 and the second beam group B2 intersect each other at an intersection 120 to be described later. The first laser device LD1 and the second laser device LD2 emit beams in an in-plane direction parallel to an xz plane.

In the first laser device LD1, a plurality of light emitting points is arranged in a first direction that is a direction parallel to the y-axis direction. The light emitting points disposed in the first laser device LD1 emit beams having different wavelengths. That is, the first laser device LD1 emits a plurality of beams from the plurality of light emitting points to form and emit the first beam group B1. The first beam group B1, which is the plurality of beams, includes a plurality of beams having different wavelengths.

A surface on which the light emitting points are arranged in the first laser device LD1 is a surface obtained by rotating a surface parallel to a yz plane about an axis that is a direction parallel to the y-axis direction. The first laser device LD1 emits the first beam group B1 in a first emission direction perpendicular to the surface on which the light emitting points are arranged in the first laser device LD1. The first emission direction in which the first beam group B1 is emitted is a direction toward the intersection 120.

In the second laser device LD2, a plurality of light emitting points is arranged in a second direction that is a direction parallel to the y-axis direction. The light emitting points disposed in the second laser device LD2 emit beams having different wavelengths. That is, the second laser device LD2 emits a plurality of beams from the plurality of light emitting points to form and emit the second beam group B2. The second beam group B2, which is the plurality of beams, includes a plurality of beams having different wavelengths.

A surface on which the light emitting points are arranged in the second laser device LD2 is a surface obtained by rotating a surface parallel to the yz plane about an axis that is the direction parallel to the y-axis direction. The second laser device LD2 emits the second beam group B2 in a second emission direction perpendicular to the surface on which the light emitting points are arranged in the second laser device LD2. The second emission direction in which the second beam group B2 is emitted is a direction toward the intersection 120.

The rotated angle of the surface on which the light emitting points are arranged in the first laser device LD1 and the rotated angle of the surface on which the light emitting points are arranged in the second laser device LD2 are equal in magnitude but opposite in direction of rotation.

The surface on which the light emitting points are arranged in the first laser device LD1 and the surface on which the light emitting points are arranged in the second laser device LD2 are not parallel. Therefore, the first emission direction of the first beam group B1 and the second emission direction of the second beam group B2 are different directions.

A direction perpendicular to both the first direction in which the light emitting points are arranged in the first laser device LD1 and the second direction in which the light emitting points are arranged in the second laser device LD2 is a third direction. FIG. 2 illustrates a case where the first direction and the second direction are both parallel to the y axis, and the third direction is parallel to the z axis.

The first beam group B1 and the second beam group B2 not parallel to each other are incident on the converging optical system 11. The converging optical system 11 causes the first beam group B1 to converge so as to be superimposed on each other at the intersection 120 on the diffraction grating 12, and causes the second beam group B2 to converge so as to be superimposed on each other at the intersection 120 on the diffraction grating 12.

Note that the converging optical system 11 may include two converging optical systems. In this case, the converging optical system 11 includes a first converging optical system that causes the first beam group B1 to converge so as to be superimposed on each other at the intersection 120 on the diffraction grating 12, and a second converging optical system that causes the second beam group B2 to converge so as to be superimposed on each other on the diffraction grating 12.

The first beam group B1 and the second beam group B2 exiting the converging optical system 11 intersect at the intersection 120 that is a point between the first and second laser devices LD1 and LD2 and the output mirror 14. Specifically, the first beam group B1 and the second beam group B2 intersect each other such that at least parts of the first beam group B1 and the second beam group B2 are superimposed on each other at the intersection 120 that is a position on the diffraction grating 12.

Note that the diffraction grating 12 may be disposed at the intersection 120 or may be disposed near the intersection 120. That is, the diffraction grating 12 need only be disposed at a position (the intersection 120) where at least parts of the first beam group B1 and the second beam group B2 are superimposed on each other.

The diffraction grating 12 is a transmission diffraction grating. The diffraction grating 12 has a diffraction effect in a plane (first plane) of a plane 50 parallel to the xy plane. The diffraction grating 12, with its wavelength dispersion property, deflects each beam of the first beam group B1 and each beam of the second beam group B2 in the plane 50. The diffraction grating 12 thus rotates the first beam group B1 and the second beam group B2 about an axis of rotation set to an axial direction parallel to the z-axis direction, and sends the first beam group B1 and the second beam group B2 to the collimating optical system 13. That is, the diffraction grating 12 bends the first beam group B1 and the second beam group B2 by changing components of the first beam group B1 and the second beam group B2 in the x-axis direction and the y-axis direction while maintaining components thereof in the z-axis direction.

The diffraction grating 12 diffracts each of the beams included in the beam group at an angle corresponding to the wavelength, thereby converging the beams into one beam. Specifically, the diffraction grating 12 converges the first beam group B1, which includes the plurality of beams dispersed from each other, to one first beam group B1. Likewise, the diffraction grating 12 converges the second beam group B2, which includes the plurality of beams dispersed from each other, to one second beam group B2. The laser apparatus 1A can thus enhance beam condensing performance.

The condensing performance referred to herein is a property represented by a beam parameter product (BPP). The BPP is an index defined by a product of a radius of a beam waist at the time of condensing and a beam divergence half angle after condensing. The BPP is expressed in units of “mm·rad”. The smaller the value of the BPP, the higher the condensing property, which means that the beams can be condensed in a finer region. As the beams can be condensed in a finer region, a higher energy density can be obtained. In the application of laser processing, as the energy density is higher, the processing quality and the processing speed can be improved.

Many of general transmission diffraction gratings have high diffraction efficiency for one of s-polarized light and p-polarized light, and low diffraction efficiency for the other. In a case where the diffraction grating 12 in the first embodiment is such a transmission diffraction grating, for example, the diffraction grating 12 diffracts 90% or more of incident s-polarized light and transmits 50% or more of incident p-polarized light. In this case, it is desirable that the first beam group B1 and the second beam group B2 incident on the diffraction grating 12 include only s-polarized light.

However, there is a case where s-polarized light and p-polarized light are mixed in the laser light actually emitted from the laser device. Even the laser light mainly including s-polarized light may include several percent of p-polarized light. In a case where the first beam group B1 and the second beam group B2 mainly including s-polarized light are incident on the diffraction grating 12, p-polarized light included in the first beam group B1 and the second beam group B2 may be transmitted through the diffraction grating 12. In this case, the p-polarized light transmitted through the diffraction grating 12 may become stray light deviating from a normal optical path of a first external resonator using the first laser device LD1 or a second external resonator using the second laser device LD2. The generation of the stray light may cause heating of a component in the laser apparatus 1A or reduction in the output beam condensing performance. It is therefore desirable that the laser apparatus 1A can reduce the generation of the stray light.

In order to reduce the generation of the stray light, the laser apparatus 1A may be provided with a polarization splitting element, The polarization splitting element is installed between the first laser device LD1 and the diffraction grating 12 and between the second laser device LD2 and the diffraction grating 12. The degrees of polarization of the first beam group B1 and the second beam group B2 incident on the diffraction grating 12 are increased by the polarization splitting elements, whereby the laser apparatus 1A can reduce the generation of the stray light.

The collimating optical system 13 collimates the first beam group B1 and the second beam group B2 such that the first beam group B1 and the second beam group B2 are incident perpendicularly on a partial reflection surface 140 of the output mirror 14 while being spatially separated.

The output mirror 14 includes the partial reflection surface 140 that reflects a part of the first beam group B1 and the second beam group B2 and transmits the rest.

An incident surface of the partial reflection surface 140 on which the first beam group B1 and the second beam group B2 are incident is a single plane. The use of the partial reflection surface 140 having the incident surface as the single plane can realize an external resonator with a simple optical system.

In the laser apparatus 1A, the first laser device LD1 and the output mirror 14 constitute the first external resonator, and the second laser device LD2 and the output mirror 14 constitute the second external resonator. That is, the first external resonator includes the first laser device LD1 constituting one end thereof and the output mirror 14 constituting another end thereof. The second external resonator includes the second laser device LD2 constituting one end thereof and the output mirror 14 constituting another end thereof.

The first external resonator is an external resonator that causes resonance of the first beam group B1. The second external resonator is an external resonator that causes resonance of the second beam group B2. The resonance of the first beam group B1 by the first external resonator and the resonance of the second beam group B2 by the second external resonator use the partial reflection surface 140 in common. Moreover, the first external resonator and the second external resonator use the diffraction grating 12 in common.

In the first external resonator, when needed, an optical element that collimates, condenses, or rotates the first beam group B1 is inserted. In the second external resonator, when needed, an optical element that collimates, condenses, or rotates the second beam group B2 is inserted.

Each beam of the first beam group B1 propagates from the first laser device LD1 to the diffraction grating 12 in a direction parallel to the xz plane. Each beam of the first beam group B1 is bent by the diffraction grating 12, propagates in a direction non-parallel to the xz plane, and is sent to the collimating optical system 13.

Each beam of the second beam group B2 propagates from the second laser device LD2 to the diffraction grating 12 in a direction parallel to the xz plane. Each beam of the second beam group B2 is bent by the diffraction grating 12, propagates in a direction non-parallel to the xz plane, and is sent to the collimating optical system 13.

The first beam group B1 and the second beam group B2 are collimated by the collimating optical system 13 and sent to the output mirror 14. The first beam group B1 and the second beam group B2 are incident perpendicularly on the partial reflection surface 140 of the output mirror 14. The first beam group B1 and the second beam group B2 are partially reflected by the partial reflection surface 140 of the output mirror 14, and the rest is transmitted as the laser light 7.

As described above, in the laser apparatus 1A, the first beam group B1 and the second beam group B2 are tilted so that the first beam group B1 and the second beam group B2 can intersect each other at the intersection 120. As a result, the laser apparatus 1A can reduce the area of incidence of the first beam group B1 and the second beam group B2 incident on the diffraction grating 12, and thus can avoid an increase in size of the diffraction grating 12.

In addition, the laser apparatus 1A causes the first beam group B1 and the second beam group B2 to be incident on the output mirror 14 while being separated from each other, thereby being able to prevent an increase in beam intensity on the output mirror 14. Therefore, the laser apparatus 1A can prevent damage due to an increase in light intensity in the output mirror 14.

In a case where the first beam group B1 and the second beam group B2 are not tilted, a diffraction grating having a size that is twice or more the size of the diffraction grating 12 included in the laser apparatus 1A is required. Generally, it is difficult to manufacture a diffraction grating, and a manufacturing cost of a large diffraction grating is high. Therefore, when the diffraction grating 12 is downsized as in the laser apparatus 1A of the first embodiment, the manufacturing cost of the laser apparatus 1A can be reduced.

The collimating optical system 13 is, for example, two cylindrical lenses. Here, a description will be made of a configuration of a laser apparatus in the case where the collimating optical system 13 is two cylindrical lenses.

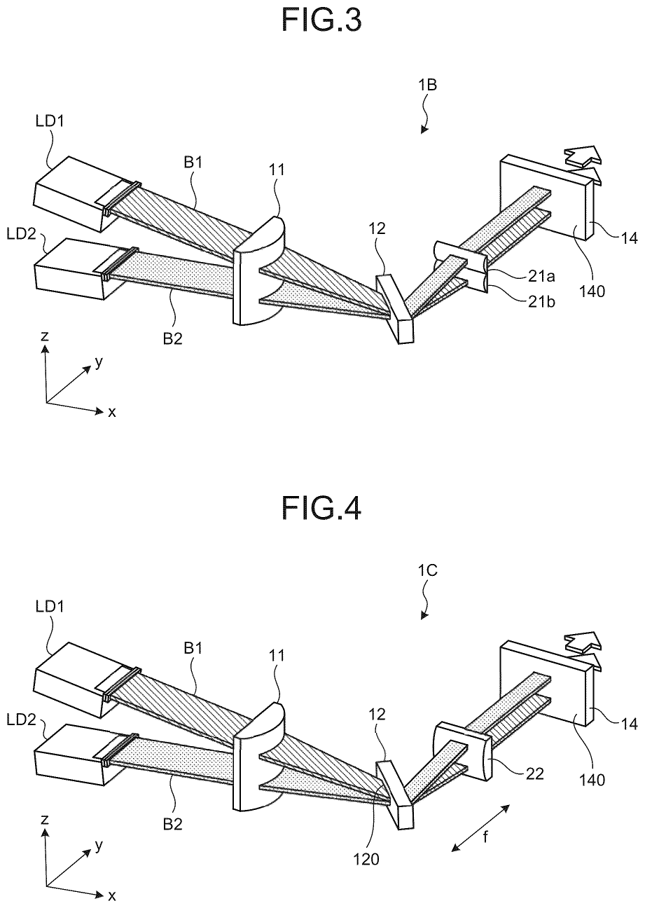

FIG. 3 is a diagram illustrating the configuration of the laser apparatus according to the first embodiment in the case where the collimating optical system is two cylindrical lenses. Components in FIG. 3 that achieve the same functions as those of the laser apparatus 1A illustrated in FIG. 2 are denoted by the same reference numerals as those in FIG. 2, and redundant description will be omitted.

A laser apparatus 1B is an example of the laser apparatus 1. The laser apparatus 1B is a laser apparatus in a case where the collimating optical system 13 is two of cylindrical lenses 21a and 21b. As with the laser apparatus 1A, the laser apparatus 1B includes the first laser device LD1, the second laser device LD2, the converging optical system 11, the diffraction grating 12, two of the cylindrical lenses 21a and 21b as an example of the collimating optical system 13, and the output mirror 14. In the laser apparatus 1B, the first laser device LD1, the second laser device LD2, the converging optical system 11, the diffraction grating 12, two of the cylindrical lenses 21a and 21b as the collimating optical system 13, and the output mirror 14 are disposed at similar positions to those in the laser apparatus 1A.

For example, among surfaces of each of the cylindrical lenses 21a and 21b, an incident surface (upper surface) on which a corresponding one of the first beam group B1 and the second beam group B2 is incident is a convex surface, and an exit surface (lower surface) from which a corresponding one of the first beam group B1 and the second beam group B2 exits is a flat surface. When the cylindrical lenses 21a and 21b are viewed from a direction perpendicular to the first beam group B1 exiting the diffraction grating 12 and the z-axis direction, a side surface of each of the cylindrical lenses 21a and 21b has a shape of a portion of an arc or elliptical arc on the incident surface side and is straight on the exit surface side. Note that the cylindrical lenses 21a and 21b may each have the exit surface that is a convex surface and the incident surface that is a flat surface.

The cylindrical lenses 21a and 21b are disposed side by side in a direction (z-axis direction) perpendicular to an optical axis of the first beam group B1 and an optical axis of the second beam group B2 incident on the partial reflection surface 140 of the output mirror 14.

The cylindrical lenses 21a and 21b collimate the first beam group B1 and the second beam group B2 such that the first beam group B1 and the second beam group B2 are incident perpendicularly on the partial reflection surface 140 of the output mirror 14 while being spatially separated.

The first beam group B1 emitted from the first laser device LD1 is sent to the diffraction grating 12 via the converging optical system 11. The second beam group B2 emitted from the second laser device LD2 is sent to the diffraction grating 12 via the converging optical system 11. The diffraction grating 12 rotates the first beam group B1 and the second beam group B2 about the axis of rotation set to the axial direction parallel to the z-axis direction, and sends the first beam group B1 and the second beam group B2 to the collimating optical system 13.

The first beam group B1 exiting from the diffraction grating 12 is sent to the cylindrical lens 21b, and the second beam group B2 exiting from the diffraction grating 12 is sent to the cylindrical lens 21a. The cylindrical lens 21b diffracts the first beam group B1 so that the first beam group B1 becomes a beam group in a plane parallel to the xy plane and reaches the partial reflection surface 140 of the output mirror 14. The cylindrical lens 21a diffracts the second beam group B2 so that the second beam group B2 becomes a beam group in a plane parallel to the xy plane and reaches the partial reflection surface 140 of the output mirror 14.

As described above, the cylindrical lenses 21a and 21b collimate the first beam group B1 and the second beam group B2 such that there is no overlap therebetween, and cause the first beam group B1 and the second beam group B2 that have been collimated to reach the partial reflection surface 140 of the output mirror 14. Note that the collimating optical system 13 may be an array lens in which two cylindrical lenses are joined in the z-axis direction.

Alternatively, the collimating optical system 13 may be one cylindrical lens. Here, a description will be made of a configuration of a laser apparatus in the case where the collimating optical system 13 is one cylindrical lens.

FIG. 4 is a diagram illustrating a configuration

of a laser apparatus according to the first embodiment in the case where the collimating optical system is one cylindrical lens. Components in FIG. 4 that achieve the same functions as those of the laser apparatus 1A or 1B illustrated in FIG. 2 or 3 are denoted by the same reference numerals as those in FIG. 2 or 3, and redundant description will be omitted.

A laser apparatus 1C is an example of the laser apparatus 1. The laser apparatus 1C is a laser apparatus in a case where the collimating optical system 13 is one cylindrical lens 22. As with the laser apparatus 1B, the laser apparatus 1C includes the converging optical system 11, the diffraction grating 12, the cylindrical lens 22 as an example of the collimating optical system 13, and the output mirror 14. Compared with the laser apparatus 1B, the laser apparatus 1C includes the cylindrical lens 22 instead of two of the cylindrical lenses 21a and 21b. In the laser apparatus 1C, the first laser device LD1, the second laser device LD2, the converging optical system 11, the diffraction grating 12, one unit of the cylindrical lens 22 as the collimating optical system 13, and the output mirror 14 are disposed at similar positions to those in the laser apparatus 1B.

The cylindrical lens 22 is a cylindrical lens having a focal length of “f” and disposed at a position away from the intersection 120 on the side of the partial reflection surface 140 by the distance “f” that is a first distance.

Among surfaces of the cylindrical lens 22, an incident surface (upper surface) on which the first beam group B1 and the second beam group B2 are incident is a convex surface, and an exit surface (lower surface) from which the first beam group B1 and the second beam group B2 exit is a flat surface. When the cylindrical lens 22 is viewed from a direction perpendicular to the first beam group B1 exiting the diffraction grating 12 and the z-axis direction, a side surface of the cylindrical lens 22 has a shape of a portion of an arc or elliptical arc on the incident surface side and is straight on the exit surface side. Note that the cylindrical lens 22 may have the exit surface that is a convex surface and the incident surface that is a flat surface.

The cylindrical lens 22 collimates the first beam group B1 and the second beam group B2 such that the first beam group B1 and the second beam group B2 are incident perpendicularly on the partial reflection surface 140 of the output mirror 14 while being spatially separated. That is, the cylindrical lens 22 diffracts the first beam group B1 and the second beam group B2 so that the first beam group B1 and the second beam group B2 each become a beam group in a plane parallel to the xy plane and reach the partial reflection surface 140 of the output mirror 14.

As described above, the cylindrical lens 22 collimates the first beam group B1 and the second beam group B2 such that there is no overlap therebetween, and causes the first beam group B1 and the second beam group B2 that have been collimated to reach the partial reflection surface 140 of the output mirror 14. Note that the laser apparatuses 1A to 1C may each include three or more laser devices.

As described above, in the laser apparatuses 1A to 1C of the first embodiment, the first laser device LD1 and the second laser device LD2 cause the first beam group B1 and the second beam group B2 not parallel to each other to be incident on the converging optical system 11. Then, the converging optical system 11 converges the first beam group B1 such that the first beam group B1 is superimposed on each other and converges the second beam group B2 such that the second beam group B2 is superimposed on each other in the stage subsequent to the converging optical system 11. Furthermore, the diffraction grating 12 is disposed at the intersection where the first beam group B1 and the second beam group B2 are at least partially superimposed on each other, the diffraction grating 12 having the diffraction effect in the plane 50 (plane parallel to the xy plane) perpendicular to the direction parallel to the z axis that is the direction perpendicular to the direction (direction parallel to the y-axis direction) in which the light emitting points are arranged in the first laser device LD1 and to the direction (direction parallel to the y-axis direction) in which the light emitting points are arranged in the second laser device LD2.

With such a configuration, the laser apparatuses 1A to 1C converge the first beam group B1 and converge the second beam group B2, thereby being able to output the laser light 7 of high power. Moreover, the laser apparatuses 1A to 1C can reduce the area of incidence of the first beam group B1 and the second beam group B2 incident on the diffraction grating 12, and thus can avoid an increase in size of the diffraction grating 12. Therefore, the laser apparatuses 1A to 1C can output the laser light 7 of high power using the diffraction grating 12 that is small and inexpensive.

### Second Embodiment

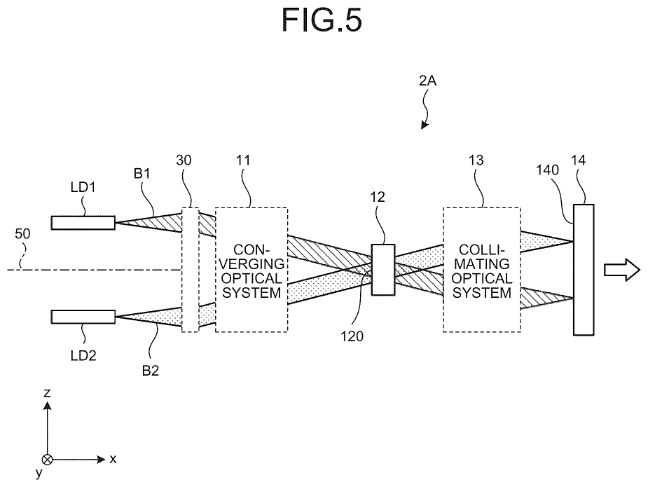

Next, a second embodiment will be described with reference to FIGS. 5 to 8. In the second embodiment, a superimposing optical system is disposed in a stage preceding the converging optical system 11 such that the first beam group B1 and the second beam group B2 emitted in parallel by the first laser device LD1 and the second laser device LD2 are superimposed in the diffraction grating 12.

FIG. 5 is a schematic diagram illustrating a schematic configuration of a laser apparatus according to the second embodiment. FIG. 5 illustrates a configuration of a laser apparatus 2A when the laser apparatus 2A is viewed from the y-axis direction. Components in FIG. 5 that achieve the same functions as those of the laser apparatus 1A illustrated in FIG. 2 are denoted by the same reference numerals as those in FIG. 2, and redundant description will be omitted.

The laser apparatus 2A is an example of the laser apparatus 1. The laser apparatus 2A is different from the laser apparatus 1A in the orientations in which the first laser device LD1 and the second laser device LD2 are disposed. Moreover, the laser apparatus 2A includes a superimposing optical system 30 in addition to the components included in the laser apparatus 1A. That is, the laser apparatus 2A includes the superimposing optical system 30, the converging optical system 11, the diffraction grating 12, the collimating optical system 13, and the output mirror 14.

The superimposing optical system 30 is disposed in a stage subsequent to the first and second laser devices LD1 and LD2 and preceding the converging optical system 11.

In the laser apparatus 2A, the first laser device LD1 and the second laser device LD2 are disposed apart from each other in the z-axis direction. The first laser device LD1 and the second laser device LD2 are disposed in parallel, and each emit beams in a direction parallel to the x-axis direction.

The surface on which the light emitting points are arranged in the first laser device LD1 is a surface parallel to the yz plane. The surface on which the light emitting points are arranged in the second laser device LD2 is a surface parallel to the yz plane. Thus, the surface on which the light emitting points are arranged in the first laser device LD1 and the surface on which the light emitting points are arranged in the second laser device LD2 are parallel to each other. Therefore, the first emission direction of the first beam group B1 and the second emission direction of the second beam group B2 are parallel to each other.

The superimposing optical system 30 changes the direction of travel of the first beam group B1 and the second beam group B2 such that the first beam group B1 and the second beam group B2 are each incident on the converging optical system 11 at the angle of incidence described in the first embodiment. That is, the superimposing optical system 30 converges the first beam group B1 and the second beam group B2 such that the first beam group B1 and the second beam group B2 intersect at the intersection 120. The superimposing optical system 30 changes the optical axis directions of the first beam group B1 and the second beam group B2.

The superimposing optical system 30 changes the optical axis direction of the first beam group B1 from a direction parallel to the x-axis to an optical axis direction rotated in a plane parallel to the xz plane. The superimposing optical system 30 changes the optical axis direction of the second beam group B2 from a direction parallel to the x-axis to an optical axis direction rotated in a plane parallel to the xz plane. The angle by which the first beam group B1 is rotated and the angle by which the second beam group B2 is rotated are equal in magnitude and opposite in direction of rotation. The converging optical system 11, the diffraction grating 12, the collimating optical system 13, and the output mirror 14 are the same as those in the first embodiment.

As described above, in the laser apparatus 2A, the first beam group B1 and the second beam group B2 are tilted so that, as with the laser apparatus 1A of the first embodiment, it is possible to avoid an increase in size of the diffraction grating 12 and to prevent an increase in beam intensity on the output mirror 14.

The superimposing optical system 30 is, for example, two eccentric lenses. Here, a description will be made of a configuration of a laser apparatus in the case where the superimposing optical system 30 is two eccentric lenses.

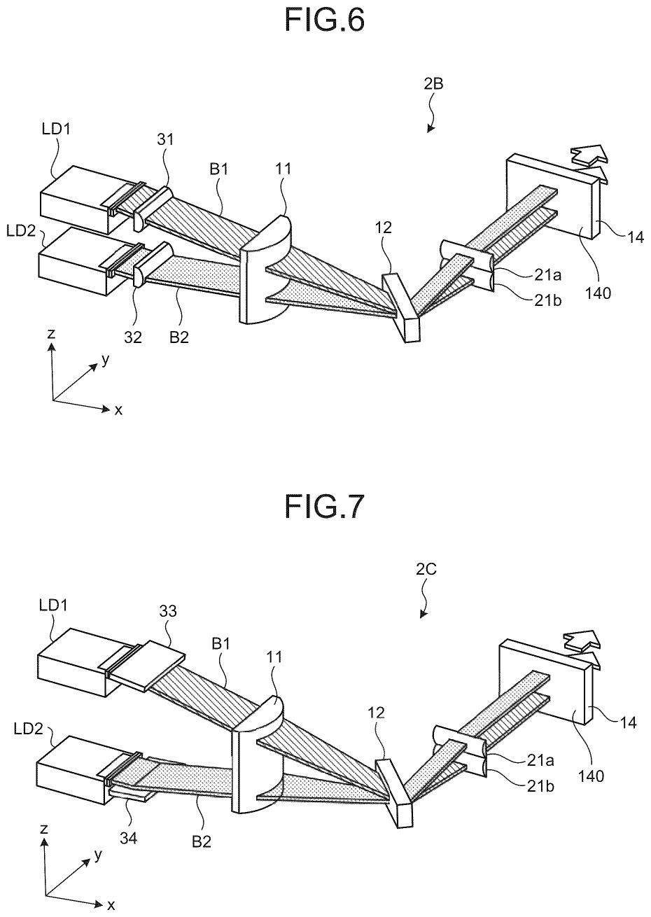

FIG. 6 is a diagram illustrating the configuration of the laser apparatus according to the second embodiment in the case where the superimposing optical system is two eccentric lenses. Components in FIG. 6 that achieve the same functions as those of the laser apparatus 2A illustrated in FIG. 5 are denoted by the same reference numerals as those in FIG. 5, and redundant description will be omitted. Note that the second embodiment will describe a case where the collimating optical system 13 is the cylindrical lenses 21a and 21b, but the collimating optical system 13 may be the cylindrical lens 22.

A laser apparatus 2B is an example of the laser apparatus 1. The laser apparatus 2B is a laser apparatus in a case where the superimposing optical system 30 is two eccentric lenses 31 and 32. As with the laser apparatus 2A, the laser apparatus 2B includes two of the eccentric lenses 31 and 32 as the superimposing optical system 30, the converging optical system 11, the diffraction grating 12, the cylindrical lenses 21a and 21b as the collimating optical system 13, and the output mirror 14. The eccentric lens 31 is a first eccentric lens, and the eccentric lens 32 is a second eccentric lens. The eccentric lenses 31 and 32 are, for example, cylindrical lenses.

In the laser apparatus 2B, the first laser device LD1, the second laser device LD2, the superimposing optical system 30 (which is two of the eccentric lenses 31 and 32 here), the converging optical system 11, the diffraction grating 12, the collimating optical system 13 (which is the cylindrical lenses 21a and 21b here), and the output mirror 14 are disposed at similar positions to those in the laser apparatus 2A.

The eccentric lens 31 is disposed eccentrically to the side of the second laser device LD2 between the first laser device LD1 and the diffraction grating 12. The eccentric lens 32 is disposed eccentrically to the side of the first laser device LD1 between the second laser device LD2 and the diffraction grating 12.

Among surfaces of each of the eccentric lenses 31 and 32, an incident surface (upper surface) on which a corresponding one of the first beam group B1 and the second beam group B2 is incident is a flat surface, and an exit surface (lower surface) from which a corresponding one of the first beam group B1 and the second beam group B2 exits is a convex surface. When the eccentric lenses 31 and 32 are viewed from a direction perpendicular to the first beam group B1 incident on the converging optical system 11 and the z-axis direction, a side surface of each of the eccentric lenses 31 and 32 has a shape of a portion of an arc or elliptical arc on the exit surface side and is straight on the incident surface side. Note that the eccentric lenses 31 and 32 may each have the incident surface that is a convex surface and the exit surface that is a flat surface.

In the laser apparatus 2B, the first beam group B1 emitted from the first laser device LD1 is sent to the eccentric lens 31. The second beam group B2 emitted from the second laser device LD2 is sent to the eccentric lens 32.

The eccentric lens 31 rotates the first beam group B1 parallel to the x-axis direction about an axis of rotation that is a direction parallel to the y-axis direction. The eccentric lens 32 rotates the second beam group B2 parallel to the x-axis direction about an axis of rotation that is a direction parallel to the y-axis direction. As a result, the first beam group B1 and the second beam group B2 are each incident on the converging optical system 11 at the angle of incidence described with reference to FIG. 5 and in the first embodiment. The converging optical system 11, the diffraction grating 12, the collimating optical system 13, and the output mirror 14 are the same as those in the first embodiment.

As described above, the superimposing optical system 30 includes the eccentric lenses 31 and 32 so that, by amounts of eccentricity of the eccentric lenses 31 and 32, the intersection angle between the first beam group B1 and the second beam group B2 can be easily changed.

Note that the superimposing optical system 30 may include only one of the eccentric lenses 31 and 32. In this case, the superimposing optical system 30 includes either one of the eccentric lenses 31 and 32 and the components other than the eccentric lenses 31 and 32. Thus, the superimposing optical system 30 only needs to include at least one of the eccentric lenses 31 and 32.

Note that the superimposing optical system 30 may be a deflection mirror. Here, a description will be made of a configuration of a laser apparatus in the case where the superimposing optical system 30 is the deflection mirror.

FIG. 7 is a diagram illustrating the configuration of the laser apparatus according to the second embodiment in the case where the superimposing optical system is two deflection mirrors. Components in FIG. 7 that achieve the same functions as those of the laser apparatus 2A or 2B illustrated in FIG. 5 or 6 are denoted by the same reference numerals as those in FIG. 5 or 6, and redundant description will be omitted.

A laser apparatus 2C is an example of the laser apparatus 1. The laser apparatus 2C is a laser apparatus in a case where the superimposing optical system 30 is deflection mirrors 33 and 34. As with the laser apparatus 2A, the laser apparatus 20 includes two of the deflection mirrors 33 and 34 as the superimposing optical system 30, the converging optical system 11, the diffraction grating 12, the cylindrical lenses 21a and 21b as the collimating optical system 13, and the output mirror 14. The deflection mirror 33 is a first deflection mirror, and the deflection mirror 34 is a second deflection mirror.

In the laser apparatus 2C, the first laser device LD1, the second laser device LD2, the superimposing optical system 30 (which is two of the deflection mirrors 33 and 34), the converging optical system 11, the diffraction grating 12, the collimating optical system 13 (which is the cylindrical lenses 21a and 21b), and the output mirror 14 are disposed at similar positions to those in the laser apparatus 2A.

The deflection mirror 33 is disposed between the first laser device LD1 and the diffraction grating 12, and deflects the first beam group B1. The deflection mirror 34 is disposed between the second laser device LD2 and the diffraction grating 12, and deflects the second beam group B2.

In the laser apparatus 2C, the first beam group B1 emitted from the first laser device LD1 is sent to the deflection mirror 33. The second beam group B2 emitted from the second laser device LD2 is sent to the deflection mirror 34.

The deflection mirror 33 rotates the first beam group B1 parallel to the x-axis direction about an axis of rotation that is a direction parallel to the y-axis direction. The deflection mirror 34 rotates the second beam group B2 parallel to the x-axis direction about an axis of rotation that is a direction parallel to the y-axis direction, As a result, the first beam group B1 and the second beam group B2 are each incident on the converging optical system 11 at the angle of incidence described with reference to FIGS. 5 and 6 and in the first embodiment. The converging optical system 11, the diffraction grating 12, the collimating optical system 13, and the output mirror 14 are the same as those in the first embodiment.

As described above, the superimposing optical system 30 includes the deflection mirrors 33 and 34 so that, by angles of installation of the deflection mirrors 33 and 34, the intersection angle between the first beam group B1 and the second beam group B2 can be easily changed.

Note that the superimposing optical system 30 may include only one of the deflection mirrors 33 and 34. In this case, the superimposing optical system 30 includes either one of the deflection mirrors 33 and 34 and the components other than the deflection mirrors 33 and 34. Thus, the superimposing optical system 30 only needs to include at least one of the deflection mirrors 33 and 34. For example, the superimposing optical system 30 may include the eccentric lens 31 and the deflection mirror 34, or may include the eccentric lens 32 and the deflection mirror 33.

Moreover, the first laser device LD1 may be disposed at the position described in the first embodiment, and the second laser device LD2 may be disposed at the position described in the second embodiment. In this case, the eccentric lens 32 or the deflection mirror 34 is disposed in the stage subsequent to the second laser device LD2.

Alternatively, the second laser device LD2 may be disposed at the position described in the first embodiment, and the first laser device LD1 may be disposed at the position described in the second embodiment. In this case the eccentric lens 31 or the deflection mirror 33 is disposed in the stage subsequent to the first laser device LD1.

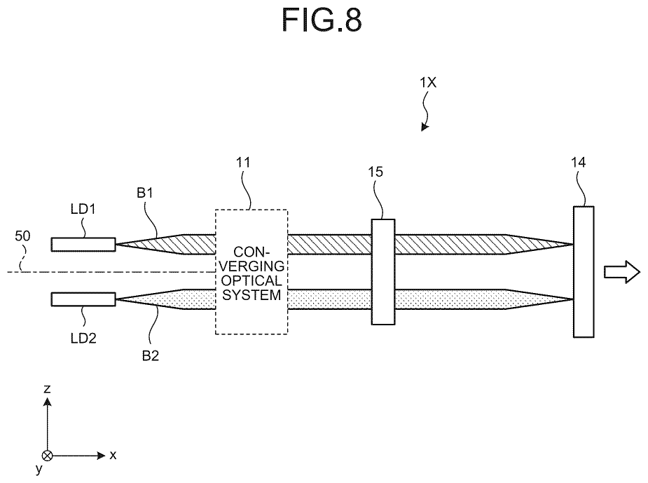

Here, a laser apparatus of a comparative example will be described. FIG. 8 is a schematic diagram illustrating a schematic configuration of the laser apparatus of the comparative example. A laser apparatus 1X of the comparative example includes the first laser device LD1, the second laser device LD2, the converging optical system 11, a diffraction grating 15, and the output mirror 14.

In the laser apparatus 1X of the comparative example, the first laser device LD1 and the second laser device LD2 are disposed in parallel. The first laser device LD1 and the second laser device LD2 are disposed apart from each other in the z-axis direction. The first laser device LD1 emits the first beam group B1 in a direction parallel to the x-axis direction, and the second laser device LD2 emits the second beam group B2 in a direction parallel to the x-axis direction.

In the laser apparatus 1X of the comparative example, the first beam group B1 and the second beam group B2 are incident on the converging optical system 11 while being apart from each other. The converging optical system 11 causes the first beam group B1 to converge so as to be superimposed on each other on the diffraction grating 15, and causes the second beam group B2 to converge so as to be superimposed on each other on the diffraction grating 15.

The diffraction grating 15 rotates the first beam group B1 and the second beam group B2 about an axis of rotation that is an axial direction parallel to the z-axis direction, and sends the first beam group B1 and the second beam group B2 to the output mirror 14. Since the first beam group B1 and the second beam group B2 incident on the diffraction grating 15 are apart from each other, the diffraction grating 15 has a longer dimension in the z-axis direction than the diffraction grating 12. For this reason, the diffraction grating 15 is more expensive than the diffraction grating 12, and the manufacturing cost of the laser apparatus 1X is higher than that of the laser apparatus 1A.

As described above, according to the second embodiment, the superimposing optical system 30 converges the first beam group B1 and the second beam group B2 such that the first beam group B1 and the second beam group B2 intersect at the intersection 120, whereby the laser light 7 of high power can be output using the diffraction grating 12 that is small and inexpensive, as in the first embodiment.

The configurations illustrated in the above embodiments each illustrate an example so that another known technique can be combined, the embodiments can be combined together, or the configurations can be partially omitted and/or modified without departing from the scope of the present disclosure.

### REFERENCE SIGNS LIST

1, 1A to 1C, 1X, 2A to 2C laser apparatus; 3 condensing optical system; 4 optical fiber; 5 processing optical system; 6 workpiece; 7 laser light; 11 converging optical system; 12, 15 diffraction grating; 13 collimating optical system; 14 output mirror; 21a, 21b, 22 cylindrical lens; 30 superimposing optical system; 31, 32 eccentric lens; 33, 34 deflection mirror; 50 plane; 100 laser processing machine; 120 intersection; 140 partial reflection surface; B1 first beam group; B2 second beam group; LD1 first laser device; LD2 second laser device.

1. A laser apparatus comprising:
a first laser device to emit a beam from each of a plurality of light emitting points, which is arranged in a first direction, in a first emission direction perpendicular to the first direction and form a first beam group;
a second laser device to emit a beam from each of a plurality of light emitting points, which is arranged in a second direction, in a second emission direction perpendicular to the second direction and form a second beam group;
an output mirror constituting one end of a first external resonator, another end of which is constituted by the first laser device, constituting one end of a second external resonator, another end of which is constituted by the second laser device, and including a partial reflection surface that reflects a part of the first beam group and the second beam group and transmits the rest;
a converging optical system to allow non-parallel incidence of the first beam group and the second beam group on the converging optical system and, on a side of a subsequent stage, converge the first beam group such that the first beam group is superimposed and converge the second beam group such that the second beam group is superimposed;
a diffraction grating disposed at an intersection at which at least a part of the first beam group and the second beam group is superimposed, and having a diffraction effect in a first plane perpendicular to a third direction that is a direction perpendicular to the first direction and the second direction; and
a collimating optical system disposed between the diffraction grating and the output mirror to collimate the first beam group and the second beam group such that the first beam group and the second beam group are incident perpendicularly on the partial reflection surface while being spatially separated from each other; and
a superimposing optical system disposed in a stage preceding the converging optical system, wherein
the first laser device and the second laser device emit the first beam group and the second beam group in parallel, and
the superimposing optical system
includes at least one of a first eccentric lens or a second eccentric lens and converges the first beam group and the second beam group such that the first beam group and the second beam group intersect at the intersection, the first eccentric lens being disposed eccentrically to a side of the second laser device between the first laser device and the diffraction grating, the second eccentric lens being disposed eccentrically to a side of the first laser device between the second laser device and the diffraction grating.

2.-5. (canceled)

6. The laser apparatus according to claim 1, wherein
the collimating optical system is two cylindrical lenses lined up in a direction perpendicular to an optical axis of the first beam group and an optical axis of the second beam group incident on the partial reflection surface, or is an array lens in which the two of the cylindrical lenses are joined.

7. The laser apparatus according to claim 1, wherein
the collimating optical system is a cylindrical lens disposed at a position away from the intersection on a side of the partial reflection surface by a first distance, and having a focal length that is the first distance.

8. A laser processing machine comprising:
a laser apparatus to emit laser light;
a condensing optical system to condense the laser light;
an optical transmission line to transmit the laser light condensed by the condensing optical system; and
a processing optical system to condense the laser light transmitted through the optical transmission line on an object to be processed, wherein
the laser apparatus includes:
a first laser device to emit a beam from each of a plurality of light emitting points, which is arranged in a first direction, in a first emission direction perpendicular to the first direction and form a first beam group;
a second laser device to emit a beam from each of a plurality of light emitting points, which is arranged in a second direction, in a second emission direction perpendicular to the second direction and form a second beam group;
an output mirror constituting one end of a first external resonator, another end of which is constituted by the first laser device, constituting one end of a second external resonator, another end of which is constituted by the second laser device, and including a partial reflection surface that reflects a part of the first beam group and the second beam group and transmits the rest as the laser light;
a converging optical system to allow non-parallel incidence of the first beam group and the second beam group on the converging optical system and, on a side of a subsequent stage, converge the first beam group such that the first beam group is superimposed and converge the second beam group such that the second beam group is superimposed;
a diffraction grating disposed at an intersection at which at least a part of the first beam group and the second beam group is superimposed, and having a diffraction effect in a first plane perpendicular to a third direction that is a direction perpendicular to the first direction and the second direction;
a collimating optical system disposed between the diffraction grating and the output mirror to collimate the first beam group and the second beam group such that the first beam group and the second beam group are incident perpendicularly on the partial reflection surface while being spatially separated from each other; and
a superimposing optical system disposed in a stage preceding the converging optical system, wherein
the first laser device and the second laser device emit the first beam group and the second beam group in parallel, and
the superimposing optical system
includes at least one of a first eccentric lens or a second eccentric lens and converges the first beam group and the second beam group such that the first beam group and the second beam group intersect at the intersection, the first eccentric lens being disposed eccentrically to a side of the second laser device between the first laser device and the diffraction grating, the second eccentric lens being disposed eccentrically to a side of the first laser device between the second laser device and the diffraction grating.

9. A laser apparatus comprising:
a first laser device to emit a beam from each of a plurality of light emitting points, which is arranged in a first direction, in a first emission direction perpendicular to the first direction and form a first beam group;
a second laser device to emit a beam from each of a plurality of light emitting points, which is arranged in a second direction, in a second emission direction perpendicular to the second direction and form a second beam group;
an output mirror constituting one end of a first external resonator, another end of which is constituted by the first laser device, constituting one end of a second external resonator, another end of which is constituted by the second laser device, and including a partial reflection surface that reflects a part of the first beam group and the second beam group and transmits the rest;
a converging optical system to allow non-parallel incidence of the first beam group and the second beam group on the converging optical system and, on a side of a subsequent stage, converge the first beam group such that the first beam group is superimposed and converge the second beam group such that the second beam group is superimposed;
a diffraction grating disposed at an intersection at which at least a part of the first beam group and the second beam group is superimposed, and having a diffraction effect in a first plane perpendicular to a third direction that is a direction perpendicular to the first direction and the second direction;
a collimating optical system disposed between the diffraction grating and the output mirror to collimate the first beam group and the second beam group such that the first beam group and the second beam group are incident perpendicularly on the partial reflection surface while being spatially separated from each other; and
a superimposing optical system disposed in a stage preceding the converging optical system, wherein
the first laser device and the second laser device emit the first beam group and the second beam group in parallel, and
the superimposing optical system
includes at least one of a first deflection mirror or a second deflection mirror and converges the first beam group and the second beam group such that the first beam group and the second beam group intersect at the intersection, the first deflection mirror being disposed between the first laser device and the diffraction grating and deflecting the first beam group, the second deflection mirror being disposed between the second laser device and the diffraction grating and deflecting the second beam group.

10. The laser apparatus according to claim 9, wherein
the collimating optical system is two cylindrical lenses lined up in a direction perpendicular to an optical axis of the first beam group and an optical axis of the second beam group incident on the partial reflection surface, or is an array lens in which the two of the cylindrical lenses are joined.

11. The laser apparatus according to claim 9, wherein
the collimating optical system is a cylindrical lens disposed at a position away from the intersection on a side of the partial reflection surface by a first distance, and having a focal length that is the first distance.

12. A laser processing machine comprising:
a laser apparatus to emit laser light;
a condensing optical system to condense the laser light;
an optical transmission line to transmit the laser light condensed by the condensing optical system; and
a processing optical system to condense the laser light transmitted through the optical transmission line on an object to be processed, wherein
the laser apparatus includes:
a first laser device to emit a beam from each of a plurality of light emitting points, which is arranged in a first direction, in a first emission direction perpendicular to the first direction and form a first beam group;
a second laser device to emit a beam from each of a plurality of light emitting points, which is arranged in a second direction, in a second emission direction perpendicular to the second direction and form a second beam group;
an output mirror constituting one end of a first external resonator, another end of which is constituted by the first laser device, constituting one end of a second external resonator, another end of which is constituted by the second laser device, and including a partial reflection surface that reflects a part of the first beam group and the second beam group and transmits the rest as the laser light;
a converging optical system to allow non-parallel incidence of the first beam group and the second beam group on the converging optical system and, on a side of a subsequent stage, converge the first beam group such that the first beam group is superimposed and converge the second beam group such that the second beam group is superimposed;
a diffraction grating disposed at an intersection at which at least a part of the first beam group and the second beam group is superimposed, and having a diffraction effect in a first plane perpendicular to a third direction that is a direction perpendicular to the first direction and the second direction;
a collimating optical system disposed between the diffraction grating and the output mirror to collimate the first beam group and the second beam group such that the first beam group and the second beam group are incident perpendicularly on the partial reflection surface while being spatially separated from each other; and
a superimposing optical system disposed in a stage preceding the converging optical system, wherein
the first laser device and the second laser device emit the first beam group and the second beam group in parallel, and
the superimposing optical system
includes at least one of a first deflection mirror or a second deflection mirror and converges the first beam group and the second beam group such that the first beam group and the second beam group intersect at the intersection, the first deflection mirror being disposed between the first laser device and the diffraction grating and deflecting the first beam group, the second deflection mirror being disposed between the second laser device and the diffraction grating and deflecting the second beam group.
